(19) United States
(12) Patent Application Publication
(10) Pub. No.: US 2026/0204306 A1
(43) Pub. Date: Jul. 16, 2026

(54) MEMORY DEVICE, MEMORY ARRAY AND OPERATION METHOD OF THE SAME

(71) Applicant: MACRONIX INTERNATIONAL CO., LTD., HSINCHU (TW)

(72) Inventors: Yu-Hsuan LIN, Taichung City (TW); Feng-Min LEE, Hsinchu City (TW); Yu-Yu LIN, New Taipei City (TW)

(21) Appl. No.: 19/015,956

(22) Filed: Jan. 10, 2025

(51) Int. Cl. G11C 11/22

(52) U.S. Cl. CPC G11C 11/2275; G11C 11/2255; G11C 11/2273

(57) ABSTRACT

A memory device includes a memory cell. The memory cell includes a first switch element, a second switch element and a storage element. The first switch element configured to receive a write bit line signal, and coupled to a storage node. The second switch element configured to receive a read bit line signal, and coupled to the storage node. The a storage element coupled to the storage node, and configured to receive a voltage signal and store a first data bit, wherein the memory cell is configured to store a second data bit different from the first data bit at the storage node.

### BACKGROUND

### Technical Field

The present disclosure relates to a memory technique. More particularly, the present disclosure relates to a memory device, a memory array and operation method of a memory device.

### Description Of Related Art

Ferroelectric device can store positive polarization and negative polarization in the ferroelectric film. Correspondingly, positive polarization and negative polarization can be configured to store different logic values, such that the ferroelectric device can operate as a memory device. However, the ferroelectric device may need a higher write voltage level, or have a poor endurance. Thus, techniques associated with the designing for problems described above are important issues in the field.

### SUMMARY

The present disclosure provides a memory device. The memory device includes a memory cell. The memory cell includes a first switch element, a second switch element and a storage element. The first switch element configured to receive a write bit line signal, and coupled to a storage node. The second switch element configured to receive a read bit line signal, and coupled to the storage node. The a storage element coupled to the storage node, and configured to receive a voltage signal and store a first data bit, wherein the memory cell is configured to store a second data bit different from the first data bit at the storage node.

In some embodiments, when the first data bit is written into the memory cell, one of the write bit line signal and the voltage signal has a first voltage level, and the other one of the write bit line signal and the voltage signal has a second voltage level, when reading the first data bit, the voltage signal has a third voltage level, and the third voltage level is larger than the first voltage level and is smaller than the second voltage level.

In some embodiments, when the second data bit is written into the memory cell, in response to the second data bit having a first logic value, the write bit line signal has the first voltage level, when the second data bit is written into the memory cell, in response to the second data bit having a second logic value, the write bit line signal has a fourth voltage level, the fourth voltage level is larger than the first voltage level and is smaller than the second voltage level.

In some embodiments, when the first data bit and the second data bit are read at the same time, the memory cell generates a read current signal passing through the second switch element, when the first data bit has a first logic value, a current level of the read current signal is larger than a first preset current level, and when the first data bit has a second logic value, the current level of the read current signal is smaller than the first preset current level.

In some embodiments, when each of the first data bit and the second data bit has the first logic value, the current level of the read current signal is between the first preset current level and a second preset current level, and when the first data bit and the second data bit respectively have the first logic value and the second logic value, the current level of the read current signal is larger than the second preset current level.

In some embodiments, when each of the first data bit and the second data bit has the second logic value, the current level of the read current signal is between the first preset current level and a third preset current level, and when the first data bit and the second data bit respectively have the second logic value and the first logic value, the current level of the read current signal is smaller than the third preset current level.

The present disclosure provides a memory device. The memory device includes a plurality of memory cells. The plurality of memory cells includes a first memory cell, a second memory cell and a third memory cell. The first memory cell configured to receive a first read bit line signal, a first read signal and a first voltage signal. The second memory cell configured to receive at least one of the first read bit line signal and the first read signal. The third memory cell configured to receive at least one of the first read bit line signal, the first read signal and the first voltage signal, wherein when a first data bit is written into the first memory cell, the first voltage signal has a first voltage level, when a second data bit is written into the first memory cell, in response to the second data bit having a first logic value, the first voltage signal has a second voltage level larger than the first voltage level, and when the second data bit is written into the first memory cell, in response to the second data bit having a second logic value, the first voltage signal has the first voltage level.

In some embodiments, the second memory cell is configured to receive each of the first read bit line signal and the first read signal, the third memory cell is configured to receive the first voltage signal, when the first data bit is read, each of the first voltage signal and the first read signal has a third voltage level larger than the first voltage level, and the first read bit line signal has a fourth voltage level larger than the first voltage level.

In some embodiments, a switch element in the first memory cell is configured to receive each of the first read bit line signal and the first read signal, and has a threshold voltage level, when the first data bit is written into the first memory cell, in response to the first data bit having the second logic value, a control terminal of the switch element has a fifth voltage level larger than the threshold voltage level, and the fifth voltage level is smaller than the third voltage level plus the threshold voltage level.

In some embodiments, each of the first memory cell and the third memory cell is configured to receive a first write bit line signal, when the second data bit is written into the first memory cell, in response to the second data bit having the first logic value, the first write bit line signal has the first voltage level, and when the second data bit is written into the first memory cell, in response to the second data bit having the second logic value, the first write bit line signal has the second voltage level.

In some embodiments, each of the first memory cell and the second memory cell is configured to receive a first write bit line signal, the third memory cell is configured to receive a second write bit line signal, when the second data bit is written into the first memory cell, in response to the second data bit having the first logic value, the first write bit line signal and the second write bit line signal have the first voltage level and the second voltage level, respectively, and when the second data bit is written into the first memory cell, in response to the second data bit having the second logic value, the first write bit line signal and the second write bit line signal have the second voltage level and the first voltage level, respectively.

In some embodiments, the second memory cell is configured to receive the first read signal, the third memory cell is configured to receive the first read bit line signal, when at least one of the first data bit and the second data bit is read, the first read signal and the first read bit line signal have the first voltage level and a third voltage level, respectively, to read the first memory cell and the third memory cell at the same time, and the third voltage level is larger than the first voltage level and is smaller than the second voltage level.

In some embodiments, each of the first memory cell and the third memory cell is configured to receive a first write bit line signal and the first voltage signal, when the second data bit is written into the first memory cell, in response to the second data bit having the first logic value, the first write bit line signal has the first voltage level, and when the second data bit is written into the first memory cell, in response to the second data bit having the second logic value, the first write bit line signal has the second voltage level.

In some embodiments, each of the first memory cell and the third memory cell is configured to receive a first write bit line signal and , the second memory cell is configured to receive a second write bit line signal and the first voltage signal, when the second data bit is written into the first memory cell, in response to the second data bit having the first logic value, the first write bit line signal and the second write bit line signal have the first voltage level and the second voltage level, respectively, and when the second data bit is written into the first memory cell, in response to the second data bit having the second logic value, the first write bit line signal and the second write bit line signal have the second voltage level and the first voltage level, respectively.

In some embodiments, the second memory cell is configured to receive the first read bit line signal, the third memory cell is configured to receive the first read signal, when at least one of the first data bit and the second data bit is read, the first read signal and the first read bit line signal have the first voltage level and a third voltage level, respectively, to read the first memory cell and the second memory cell at the same time, and the third voltage level is larger than the first voltage level and is smaller than the second voltage level.

In some embodiments, each of the first memory cell and the third memory cell is configured to receive a first write bit line signal and the first voltage signal, when the second data bit is written into the first memory cell, in response to the second data bit having the first logic value, the first write bit line signal has the first voltage level, and when the second data bit is written into the first memory cell, in response to the second data bit having the second logic value, the first write bit line signal has the second voltage level.

In some embodiments, each of the first memory cell and the third memory cell is configured to receive a first write bit line signal and , the second memory cell is configured to receive a second write bit line signal and the first voltage signal, when the second data bit is written into the first memory cell, in response to the second data bit having the first logic value, the first write bit line signal and the second write bit line signal have the first voltage level and the second voltage level, respectively, and when the second data bit is written into the first memory cell, in response to the second data bit having the second logic value, the first write bit line signal and the second write bit line signal have the second voltage level and the first voltage level, respectively.

The present disclosure provides an operation method of a memory device. The operation method includes: receiving a write bit line signal by a first switch element coupled to a storage node; receiving a read bit line signal by a second switch element coupled to the storage node; receiving a voltage signal by a storage element coupled to the storage node; storing a first data bit by the storage element; and storing a second data bit different from the first data bit at the storage node.

In some embodiments, the operation method further includes: when the first data bit and the second data bit are read at the same time, generating a read current signal passing through the second switch element, wherein when the first data bit has a first logic value, a current level of the read current signal is larger than a first preset current level, and when the first data bit has a second logic value, the current level of the read current signal is smaller than the first preset current level.

In some embodiments, when each of the first data bit and the second data bit has the first logic value, the current level of the read current signal is between the first preset current level and a second preset current level, when the first data bit and the second data bit respectively have the first logic value and the second logic value, the current level of the read current signal is larger than the second preset current level, when each of the first data bit and the second data bit has the second logic value, the current level of the read current signal is between the first preset current level and a third preset current level, and when the first data bit and the second data bit respectively have the second logic value and the first logic value, the current level of the read current signal is smaller than the third preset current level.

It is to be understood that both the foregoing general description and the following detailed description are examples, and are intended to provide further explanation of the disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a part of a memory device illustrated according to some embodiments of present disclosure.

FIG. 1B is a schematic diagram of a memory device corresponding to the memory device shown in FIG. 1A, illustrated according to some embodiments of present disclosure.

FIG. 2A is a schematic diagram of the memory cell performing the write operation in nonvolatile mode, illustrated according to some embodiments of present disclosure.

FIG. 2B is a schematic diagram of the memory cell performing the read operation in nonvolatile mode, illustrated according to some embodiments of present disclosure.

FIG. 2C is a schematic diagram of the read current signal during the read operation in nonvolatile mode, illustrated according to some embodiments of present disclosure.

FIG. 3A is a schematic diagram of the memory cell performing the write operation in volatile mode, illustrated according to some embodiments of present disclosure.

FIG. 3B is a schematic diagram of the memory cell performing the read operation in volatile mode, illustrated according to some embodiments of present disclosure.

FIG. 3C is a schematic diagram of the read current signal during the read operation in volatile mode, illustrated according to some embodiments of present disclosure.

FIG. 4 is a schematic diagram of the read current signal during the read operation in the mix mode, illustrated according to some embodiments of present disclosure.

FIG. 5A to FIG. 5F are schematic diagrams of memory arrays of the memory device during the read operation in the mix mode, illustrated according to some embodiments of present disclosure.

FIG. 6 is a table of the memory device performing the read operation, illustrated according to some embodiments of present disclosure.

FIG. 7A to FIG. 7F are tables of the operations of the memory device shown in FIG. 5A to FIG. 5F, illustrated according to some embodiments of present disclosure.

### DETAILED DESCRIPTION

In the present disclosure, when an element is referred to as "connected" or "coupled", it may mean "electrically connected" or "electrically coupled". "Connected" or "coupled" can also be used to indicate that two or more components operate or interact with each other. In addition, although the terms "first", "second", and the like are used in the present disclosure to describe different elements, the terms are used only to distinguish the elements or operations described in the same technical terms. The use of the term is not intended to be a limitation of the present disclosure.

Unless otherwise defined, all terms (including technical and scientific terms) used in the present disclosure have the same meaning as commonly understood by the ordinary skilled person to which the concept of the present invention belongs. It will be further understood that terms (such as those defined in commonly used dictionaries) should be interpreted as having a meaning consistent with its meaning in the related technology and/or the context of this specification and not it should be interpreted in an idealized or overly formal sense, unless it is clearly defined as such in this article.

The terms used in the present disclosure are only used for the purpose of describing specific embodiments and are not intended to limit the embodiments. As used in the present disclosure, the singular forms "a", "one" and "the" are also intended to include plural forms, unless the context clearly indicates otherwise. It will be further understood that when used in this specification, the terms "comprises (comprising)" and/or "includes (including)" designate the existence of stated features, steps, operations, elements and/or components, but the existence or addition of one or more other features, steps, operations, elements, components, and/or groups thereof are not excluded.

Hereinafter multiple embodiments of the present disclosure will be disclosed with schema, as clearly stated, the details in many practices it will be explained in the following description. It should be appreciated, however, that the details in these practices is not applied to limit the present disclosure. Also, it is to say, in some embodiments of the present disclosure, the details in these practices are non-essential. In addition, for the sake of simplifying schema, some known usual structures and element in the drawings by a manner of simply illustrating for it.

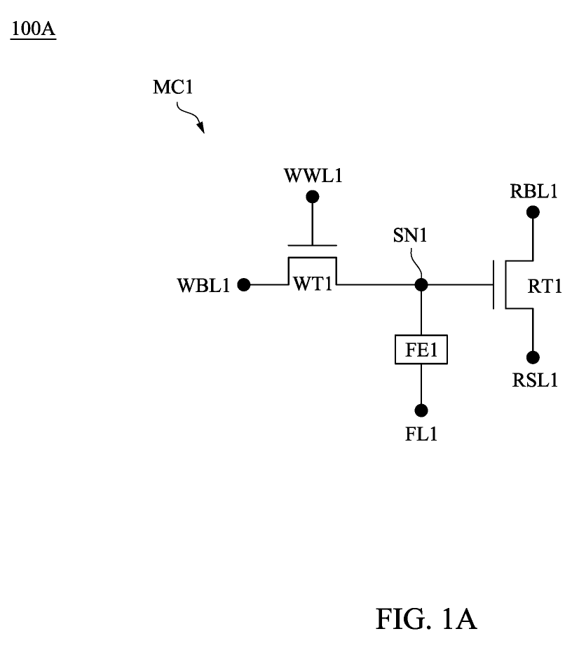

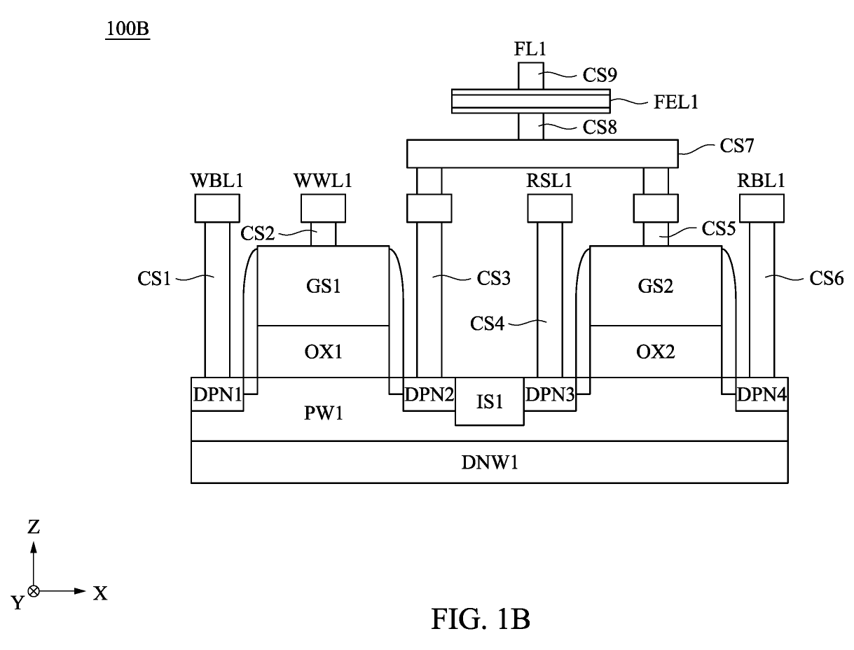

FIG. 1A is a schematic diagram of a part of a memory device 100A, illustrated according to some embodiments of present disclosure. In some embodiments, the memory device 100A includes a memory array. The memory array can includes multiple memory cells, such as a memory cell MC1.

As shown in FIG. 1A, the memory cell MC1 includes switch elements WT1, RT1 and a storage element FE1. A terminal of the switch element WT1 is configured to receive a write bit line signal WBL1, another terminal of the switch element WT1 is coupled to a storage node SN1, and a control terminal of the switch element WT1 is configured to receive a write word line signal WWL1. A terminal of the switch element RT1 is configured to receive a read bit line signal RBL1, another terminal of the switch element RT1 is configured to receive a read signal RSL1, and a control terminal of the switch element RT1 is coupled to the storage node SN1. A terminal of the storage element FE1 is coupled to the storage node SN1, and another terminal of the storage element FE1 is configured to receive a voltage signal FL1.

In some embodiments, the switch elements WT1 and RT1 can be implemented by transistors. The switch element WT1 can be referred to as a write transistor, and the switch element RT1 can be referred to as a read transistor. The storage element FE1 can be implemented by a ferroelectric layer, and can operate as a capacitor.

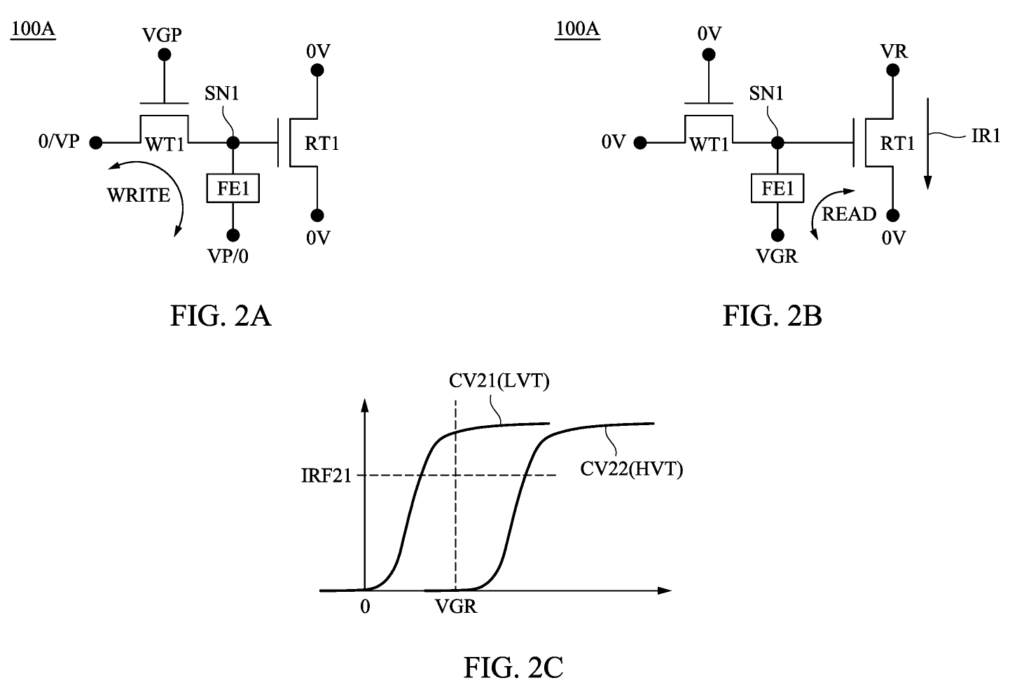

In various embodiments the memory cell MC1 can operate in a volatile mode, a nonvolatile mode and a mix mode. In the nonvolatile mode, the memory cell MC1 store a data bit NDT1 at the storage element FE1 by positive polarization and negative polarization of the storage element FE1. In the volatile mode, the memory cell MC1 store a data bit VDT1 at the storage node SN1. In the mix mode, the memory cell MC1 can store the data bits NDT1 and VDT1 simultaneously. Further details regarding the volatile mode, the nonvolatile mode and the mix mode are described below with the embodiments associated with FIG. 2A to FIG. 4.

FIG. 1B is a schematic diagram of a memory device 100B corresponding to the memory device 100A shown in FIG. 1A, illustrated according to some embodiments of present disclosure. In FIG. 1B, a Y direction points into the paper.

As shown in FIG. 1B, the memory device 100B includes well structures DNW1, PW1, doped structures DPN1-DPN4, an isolation structure IS1, oxide structures OX1, OX2, gate structures GS1, GS2, conductive structures CS1-CS9 and a ferroelectric layer FEL1.

Along a Z direction, the well structure PW1 is located above the well structure DNW1, each of the doped structures DPN1-DPN4 and the isolation structure IS1 is embedded in the well structure PW1. Each of the oxide structure OX1 and OX2 is located above the well structure PW1. The gate structures GS1 and GS2 are located above the oxide structure OX1 and OX2, respectively. The conductive structures CS1-CS6 are located above the doped structure DPN1, the gate structure GS1, the doped structures DPN2, DPN3, the gate structure GS2 and the doped structure DPN4, respectively. The conductive structure CS7 is located above the conductive structures CS3 and CS5, and is separated from the conductive structure CS4. The conductive segment CS8 is located above the conductive segment CS7. The ferroelectric layer FEL1 is located above the conductive structures CS8. The conductive structures CS9 is located above the ferroelectric layer FEL1.

Along the X direction, the doped structure DPN1, the gate structure GS1, the doped structure DPN2, the isolation structure IS1, the doped structure DPN3, the gate structure GS2 and the doped structure DPN4 are arranged in order. The isolation structure IS1 is configured to isolate the doped structures DPN2 and DPN3. The conductive segment CS7 is elongated along the X direction to be coupled to each of the conductive segments CS3 and CS5.

Referring to FIG. 1A and FIG. 1B, the memory device 100A can be implemented by the memory device 100B. Specifically, two terminals of the switch elements WT1 correspond to the doped structures DPN1 and DPN2, respectively, and the control terminal of the switch element WT1 corresponds to the gate structure GS1. Two terminals of the switch elements RT1 correspond to the doped structures DPN3 and DPN4, respectively, and the control terminal of the switch element RT1 corresponds to the gate structure GS2. The storage element FE1 corresponds to the ferroelectric layer FEL1. The storage node SN1 corresponds to the conductive structure CS7.

In the embodiment described above, the conductive structure CS1 is configured to transmit the write bit line signal WBL1 to the doped structure DPN1. The conductive structure CS2 is configured to transmit the write word line signal WWL1 to the gate structure GS1. The conductive structure CS4 is configured to transmit the read signal RSL1 to the doped structure DPN3. The conductive structure CS6 is configured to transmit the read bit line signal RBL1 to the doped structure DPN4. The doped structure DPN2 and the gate structure GS2 are coupled to each other through the conductive structures CS3, CS7 and CS5. The conductive structure CS9 is configured to transmit the voltage signal FL1 to the ferroelectric layer FEL1.

FIG. 2A is a schematic diagram of the memory cell MC1 performing the write operation in nonvolatile mode, illustrated according to some embodiments of present disclosure. In some embodiments, the write operation can be done through the switch element WT1, and program the storage element FE1 to positive polarization or negative polarization.

During the write operation, the write word line signal WWL has a voltage level VGP, such that the switch element WT1 is turned on. Each of the read bit line signal RBL1 and the read signal RSL1 has a zero-voltage level.

When the written data bit NDT1 has the logic value 0, the write bit line signal WBL1 has the zero-voltage level, and the voltage signal FL1 has a voltage level VP which is larger than the zero-voltage level, such that the storage element FE1 and the switch element RT1 have a threshold voltage level LVT.

When the written data bit NDT1 has the logic value 1, the write bit line signal WBL1 has the voltage level VP, and the voltage signal FL1 has the zero-voltage level, such that the storage element FE1 and the switch element RT1 have a threshold voltage level HVT which is larger than the threshold voltage level LVT.

FIG. 2B is a schematic diagram of the memory cell MC1 performing the read operation in nonvolatile mode, illustrated according to some embodiments of present disclosure. In some embodiments, the write operation can be done through the switch element WT1, and program the storage element FE1 to positive polarization or negative polarization.

During the read operation, the write word line signal WWL has the zero-voltage level, such that the switch element WT1 is turned off. Each of the write bit line signal WBL1 and the read signal RSL1 has the zero-voltage level. The voltage signal FL1 has a voltage level VGR, such that the switch element RT1 is turned on. The read bit line signal RBL1 has a voltage level VR which is larger than the zero-voltage level, to generate a read current signal IR1 passing through the switch element RT1. In some embodiments, the voltage level VGR is larger than the voltage level VR.

FIG. 2C is a schematic diagram of the read current signal IR1 during the read operation in nonvolatile mode, illustrated according to some embodiments of present disclosure. A horizontal axis of FIG. 2C corresponds to the voltage level of the voltage signal FL1. A vertical axis of FIG. 2C corresponds to the current level of the read current signal IR1.

In some embodiments, when the storage element FE1 and the switch element RT1 have the threshold voltage level LVT, the read current signal IR1 corresponds to the curve CV21. When the storage element FE1 and the switch element RT1 have the threshold voltage level HVT, the read current signal IR1 corresponds to the curve CV22.

As shown in FIG. 2C, when the voltage signal FL1 has the voltage level VGR, in response to the threshold voltage level LVT, the current level of the read current signal IR1 is larger than a preset current level IRF21. When the voltage signal FL1 has the voltage level VGR, in response to the threshold voltage level HVT, the current level of the read current signal IR1 is smaller than the preset current level IRF21. Correspondingly, the memory device 100 can compare the read current signal IR1 and the preset current level IRF21 to read the logic value of the data bit NDT1.

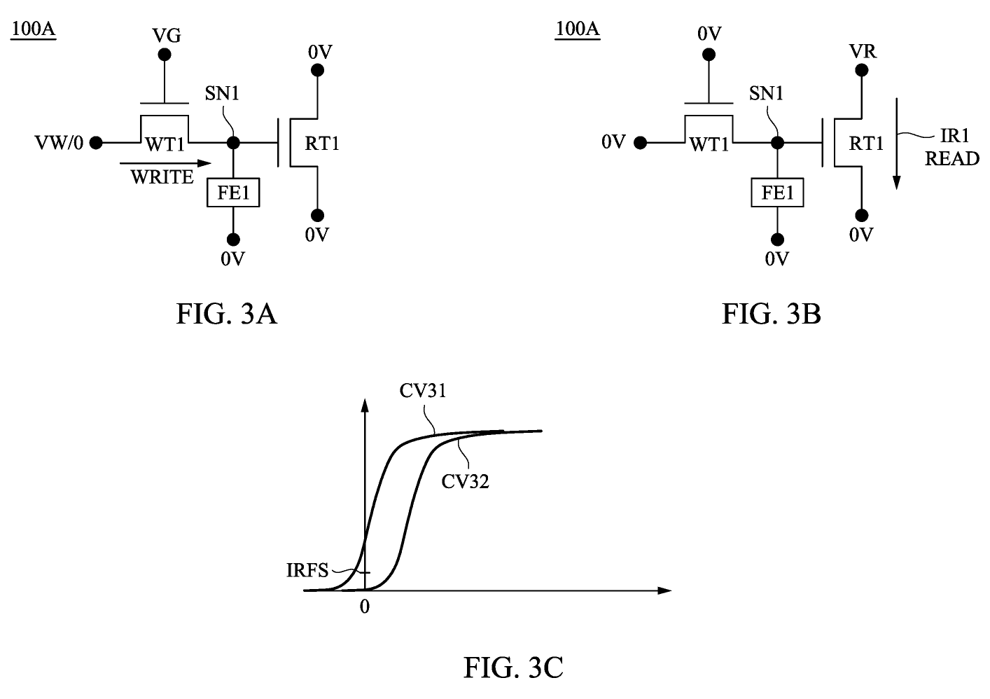

FIG. 3A is a schematic diagram of the memory cell MC1 performing the write operation in volatile mode, illustrated according to some embodiments of present disclosure. In some embodiments, in the volatile mode, the storage element FE1 has a state of the threshold voltage level LVT or the initial state. During the write operation, the storage node SN1 is charged or discharged by the switch element WT1.

Specifically, during the write operation, the write word line signal WWL has a voltage level VG, such that the switch element WT1 is turned on. Each of the read bit line signal RBL1 and the read signal RSL1 has a zero-voltage level. The voltage signal FL1 is coupled to the ground and has the zero-voltage level.

When the written data bit VDT1 has the logic value 0, the write bit line signal WBL1 has the zero-voltage level. When the written data bit VDT1 has the logic value 1, the write bit line signal WBL1 has a voltage level VW which is larger than the zero-voltage level.

FIG. 3B is a schematic diagram of the memory cell MC1 performing the read operation in volatile mode, illustrated according to some embodiments of present disclosure. During the read operation, the write word line signal WWL has the zero-voltage level, such that the switch element WT1 is turned off. Each of the voltage signal FL1, the write bit line signal WBL1 and the read signal RSL1 has the zero-voltage level. The switch element RT1 is turned on according to the voltage level of the storage node SN1. The read bit line signal RBL1 has the voltage level VR, to generate the read current signal IR1.

FIG. 3C is a schematic diagram of the read current signal IR1 during the read operation in volatile mode, illustrated according to some embodiments of present disclosure. A horizontal axis of FIG. 3C corresponds to the voltage level of the voltage signal FL1. A vertical axis of FIG. 3C corresponds to the current level of the read current signal IR1.

In some embodiments, when the data bit VDT1 stored by the storage node SN1 has the logic value 1, the read current signal IR1 corresponds to the curve CV31. When the data bit VDT1 stored by the storage node SN1 has the logic value 0, the read current signal IR1 corresponds to the curve CV32.

As shown in FIG. 3C, when the voltage signal FL1 has the zero-voltage level, in response to the logic value 1 of the storage node SN1, the current level of the read current signal IR1 is larger than a preset current level IRFS. When the voltage signal FL1 has the zero-voltage level, in response to the logic value 0 of the storage node SN1, the current level of the read current signal IR1 is smaller than a preset current level IRFS. Correspondingly, the memory device 100 can compare the read current signal IR1 and the preset current level IRFS to read the logic value of the data bit VDT1.

In some embodiments, the memory cell MC1 can further operate in the mix mode. In the mix mode, the memory cell MC1 can perform the write operation of the nonvolatile mode shown in FIG. 2A, to write the data bit NDT1 into the storage element FE1. Then, the memory cell MC1 can perform the write operation of the nonvolatile mode shown in FIG. 3A, to write the data bit VDT1 into the storage node SN1. As a result, the memory cell MC1 can store the data bits NDT1 and VDT1 simultaneously.

In some embodiments, the memory cell MC1 performs the operation shown in FIG. 2A to perform the read operation in the mix mode. When the memory cell MC1 performing the read operation in the mix mode, the write word line signal WWL has the zero-voltage level, such that the switch element WT1 is turned off. Each of the write bit line signal WBL1 and the read signal RSL1 has the zero-voltage level. The voltage signal and the read bit line signal RBL1 has the voltage levels VGR and VR, respectively, to generate the read current signal IR1.

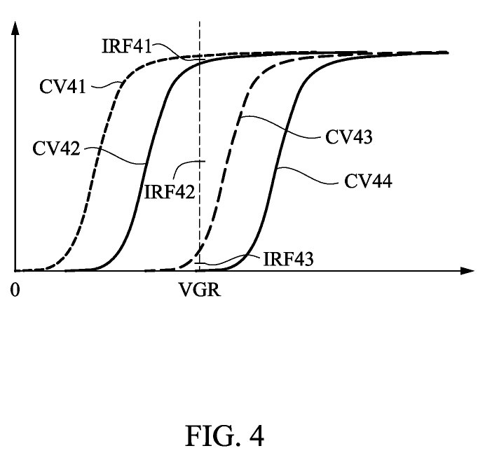

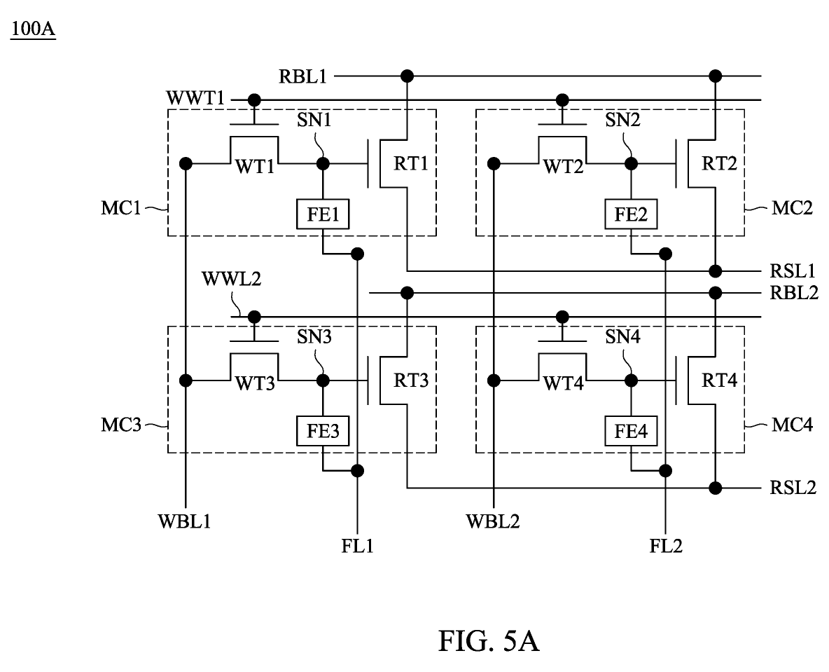

FIG. 4 is a schematic diagram of the read current signal IR1 during the read operation in the mix mode, illustrated according to some embodiments of present disclosure. A horizontal axis of FIG. 4 corresponds to the voltage level of the voltage signal FL1. A vertical axis of FIG. 4 corresponds to the current level of the read current signal IR1.

In some embodiments, when the storage element FE1 and the switch element RT1 have the threshold voltage level LVT and the data bit VDT1 stored by the storage node SN1 has the logic value 1, the read current signal IR1 corresponds to the curve CV41. When the storage element FE1 and the switch element RT1 have the threshold voltage level LVT and the data bit VDT1 stored by the storage node SN1 has the logic value 0, the read current signal IR1 corresponds to the curve CV42. When the storage element FE1 and the switch element RT1 have the threshold voltage level HVT and the data bit VDT1 stored by the storage node SN1 has the logic value 1, the read current signal IR1 corresponds to the curve CV43. When the storage element FE1 and the switch element RT1 have the threshold voltage level HVT and the data bit VDT1 stored by the storage node SN1 has the logic value 0, the read current signal IR1 corresponds to the curve CV44.

As shown in FIG. 4, when the voltage signal FL1 has the voltage level VGR, in response to the condition of the curve CV41, the current level of the read current signal IR1 is larger than a preset current level IRF41. When the voltage signal FL1 has the voltage level VGR, in response to the condition of the curve CV42, the current level of the read current signal IR1 preset current levels IRF41 and IRF42. When the voltage signal FL1 has the voltage level VGR, in response to the condition of the curve CV43, the current level of the read current signal IR1 preset current levels IRF42 and IRF43. When the voltage signal FL1 has the voltage level VGR, in response to the condition of the curve CV44, the current level of the read current signal IR1 is smaller than a preset current level IRF43.

In some embodiments, the memory device 100 can compare the read current signal IR1 and the preset current levels IRF41-IRF43 to read the logic value of the data bits VDT1 and NDT1. In some embodiments, the preset current level IRF43 is smaller than the preset current level IRF42, and the preset current level IRF42 is smaller than the preset current level IRF41.

In some embodiments, the voltage level VGP is within a voltage range between zero volt to a voltage level VDD. The voltage level VG is equal to the voltage level VDD, in which the voltage level VDD is within a voltage range between 3volts to 5 volts. The voltage level VP is within a voltage range between 3 volts to 5 volts. The voltage level VW is within a voltage range between 0.8 volts to 2 volts. The voltage level VR is within a voltage range between 0.1 volts to 0.5 volts. The voltage level VGR is within a voltage range between 0.5 volts to 2 volts. Alternatively stated, each of the voltage levels VDD and VP is larger than the voltage levels VW and VGR, and each of the voltage levels VW and VGR is larger than the voltage level VR.

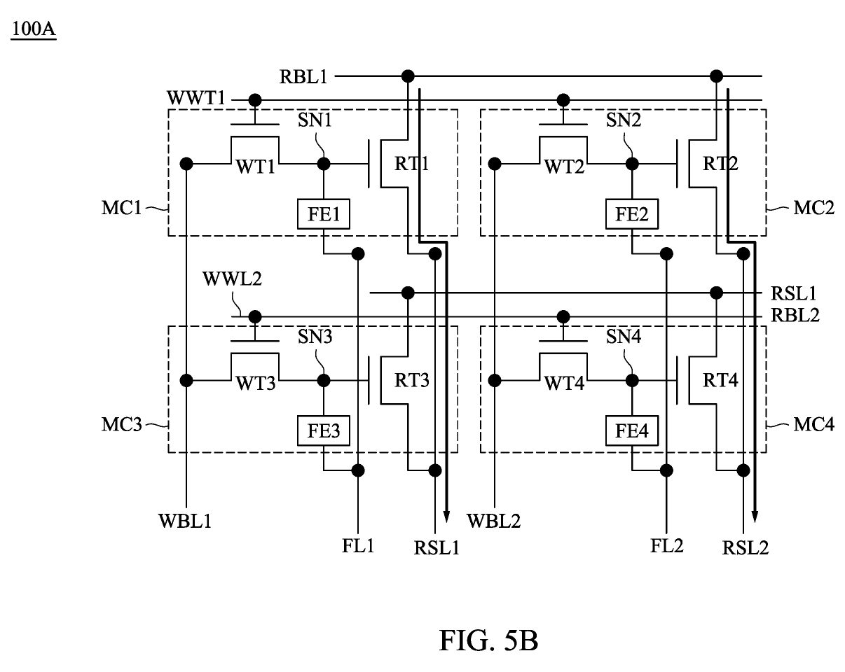

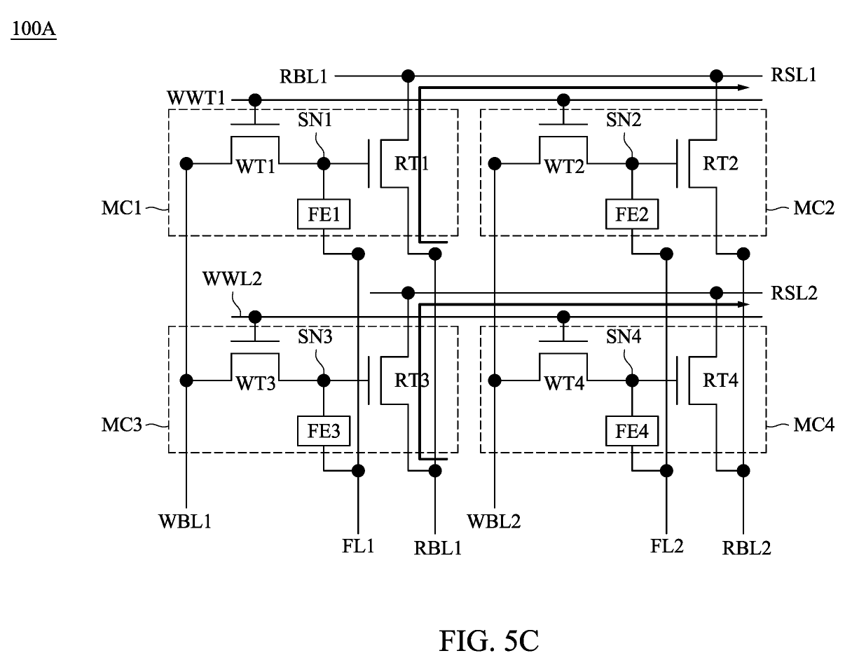

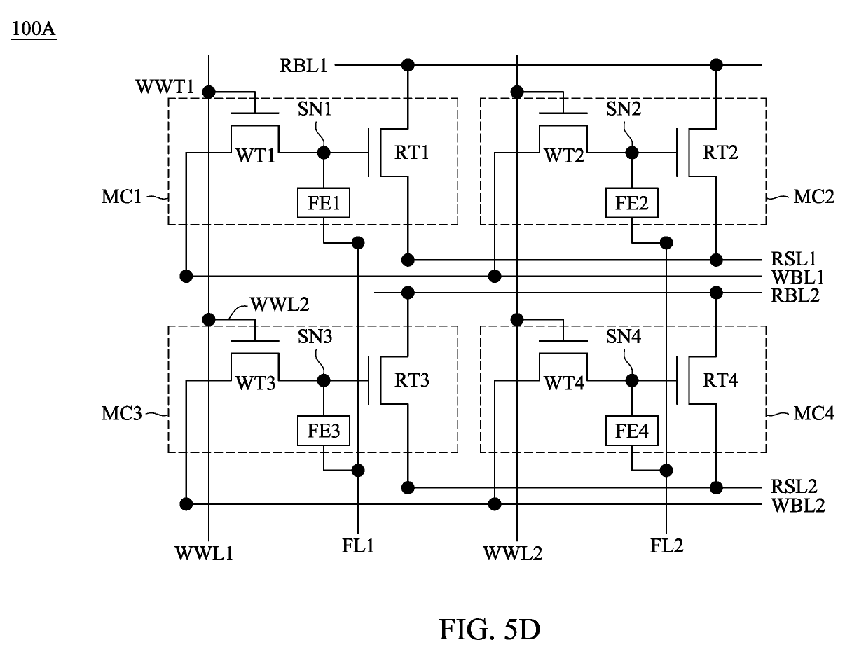

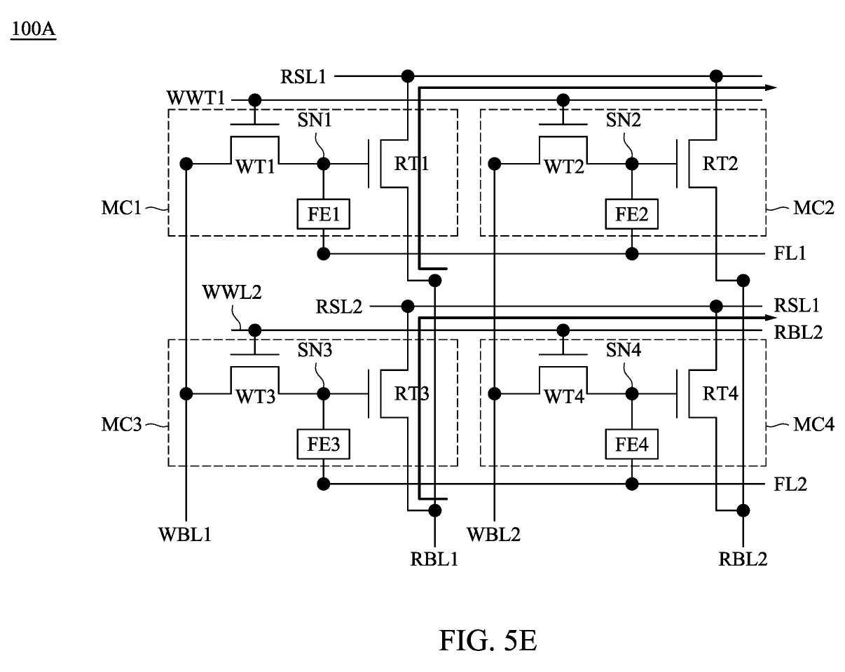

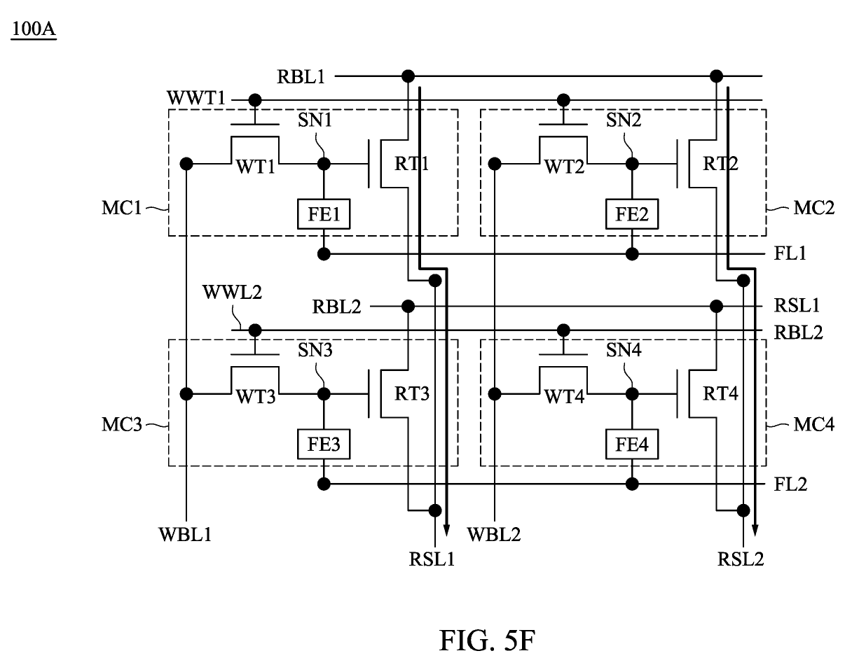

In some embodiments, multiple memory cells can be configured into various memory arrays. Further details of the various memory arrays are described below with the embodiments associated with FIG. 5A to FIG. 5F.

FIG. 5A is a schematic diagram of a memory array of the memory device 100A during the read operation in the mix mode, illustrated according to some embodiments of present disclosure. In some embodiments, a configuration of the memory array shown in FIG. 5A is referred to as a write AND plus read AND type.

As shown in FIG. 5A, the memory device 100A includes memory cells MC1-MC4. The memory cell MC2 includes switch elements WT2, RT2 and a storage element FE2. The memory cell MC2 includes switch elements WT2, RT2 and a storage element FE2. The memory cell MC3 includes switch elements WT3, RT3 and a storage element FE3. The memory cell MC4 includes switch elements WT4, RT4 and a storage element FE4.

In some embodiments, the memory cells MC2-MC4 are similar with the memory cell MC1. The switch elements WT2-WT4 and RT2-RT4 are similar with the switch elements WT1 and RT1. The storage element FE2-FE4 are similar with the storage element FE1. Therefore, for brevity, some descriptions are not repeated.

As shown in FIG. 5A, a terminal of the switch element WT2 is configured to receive a write bit line signal WBL2, another terminal of the switch element WT2 is coupled to a storage node SN2, and a control terminal of the switch element WT2 is configured to receive a write word line signal WWL1. A terminal of the switch element RT2 is configured to receive a read bit line signal RBL1, another terminal of the switch element RT2 is configured to receive a read signal RSL1, and a control terminal of the switch element RT2 is coupled to the storage node SN2. A terminal of the storage element FE2 is coupled to the storage node SN2, and another terminal of the storage element FE2 is configured to receive a voltage signal FL2.

Similarly, a terminal of the switch element WT3 is configured to receive the write bit line signal WBL1, another terminal of the switch element WT3 is coupled to a storage node SN3, and a control terminal of the switch element WT3 is configured to receive the write word line signal WWL2. A terminal of the switch element RT3 is configured to receive the read bit line signal RBL2, another terminal of the switch element RT3 is configured to receive the read signal RSL2, and a control terminal of the switch element RT3 is coupled to the storage node SN3. A terminal of the storage element FE3 is coupled to the storage node SN3, and another terminal of the storage element FE3 is configured to receive the voltage signal FL1.

Similarly, a terminal of the switch element WT4 is configured to receive the write bit line signal WBL2, another terminal of the switch element WT4 is coupled to a storage node SN4, and a control terminal of the switch element WT4 is configured to receive the write word line signal WWL2. A terminal of the switch element RT4 is configured to receive the read bit line signal RBL2, another terminal of the switch element RT4 is configured to receive the read signal RSL2, and a control terminal of the switch element RT4 is coupled to the storage node SN4. A terminal of the storage element FE4 is coupled to the storage node SN4, and another terminal of the storage element FE4 is configured to receive the voltage signal FL2.

Referring to FIG. 1A to FIG. 5A, similar to the memory cell MC1, the memory cells MC2-MC4 can store data bits at corresponding storage nodes and storage elements. For example, the memory cell MC2 can store a data bit VDT2 at the storage node SN2, and store a data bit NDT2 at the storage element FE2. The memory cell MC3 can store a data bit VDT3 at the storage node SN3, and store a data bit NDT3 at the storage element FE3. The memory cell MC4 can store a data bit VDT4 at the storage node SN4, and store a data bit NDT4 at the storage element FE4.

FIG. 5B is a schematic diagram of a memory array of the memory device 100A during the read operation in the mix mode, illustrated according to some embodiments of present disclosure. In some embodiments, a configuration of the memory array shown in FIG. 5B is referred to as a write AND plus read NOR type. Referring to FIG. 5A and FIG. 5B, the memory array shown in FIG. 5B is an alternative embodiment of the memory array shown in FIG. 5A. Therefore, for brevity, some descriptions are not repeated.

Compared to FIG. 5A, in the embodiment shown in FIG. 5B, two terminals of the switch element RT1 are configured to receive the read signal RSL1 and the read bit line signal RBL1, respectively. Two terminals of the switch element RT2 are configured to receive the read signal RSL2 and the read bit line signal RBL1, respectively. Two terminals of the switch element RT3 are configured to receive the read signal RSL1 and the read bit line signal RBL2, respectively. Two terminals of the switch element RT4 are configured to receive the read signal RSL2 and the read bit line signal RBL2, respectively.

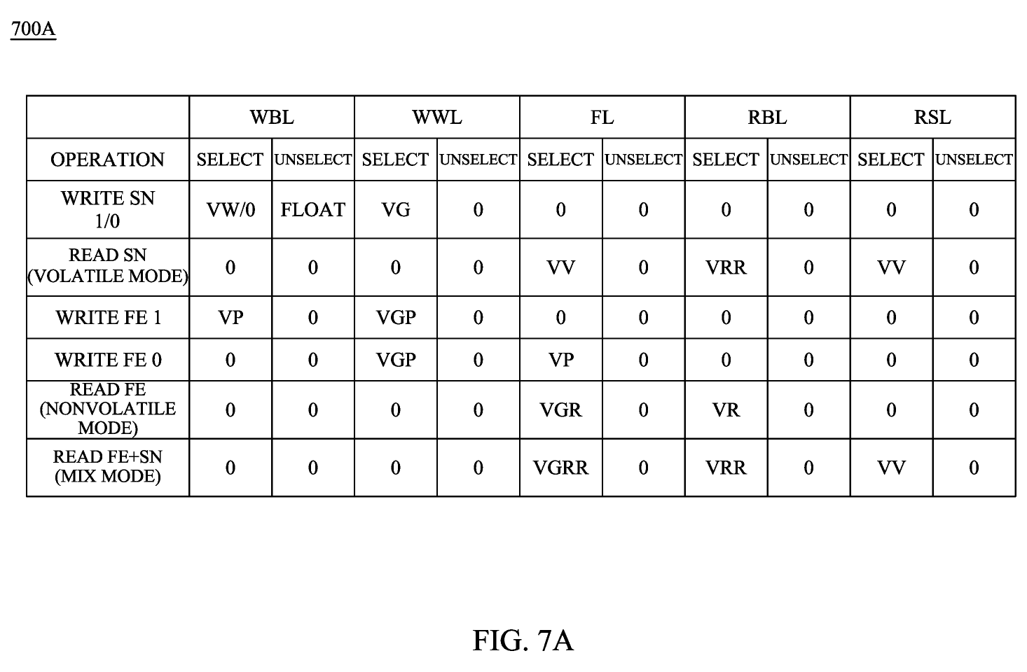

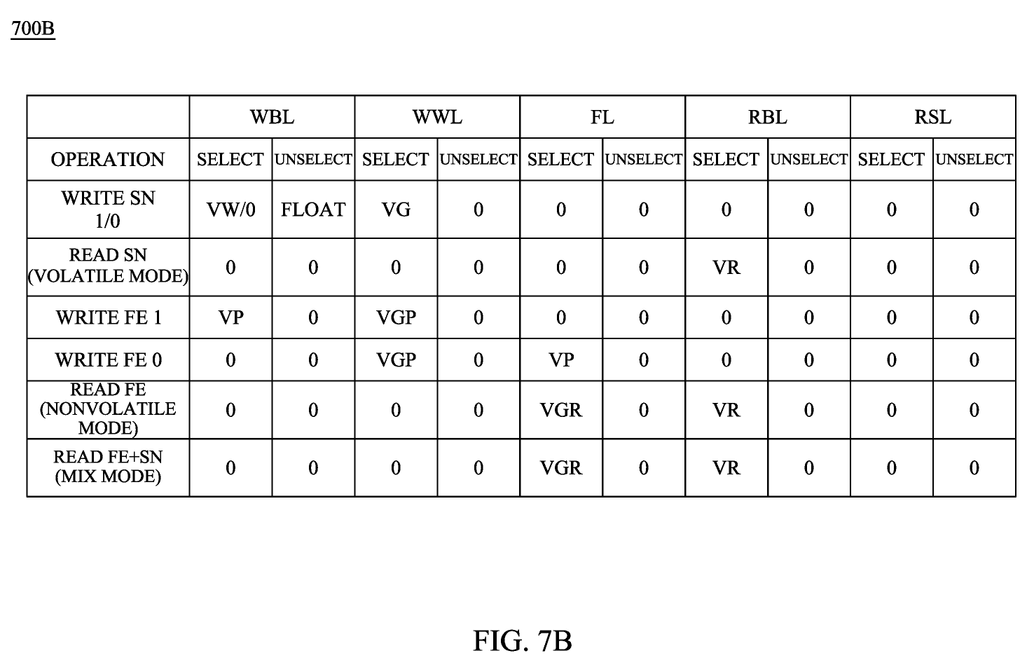

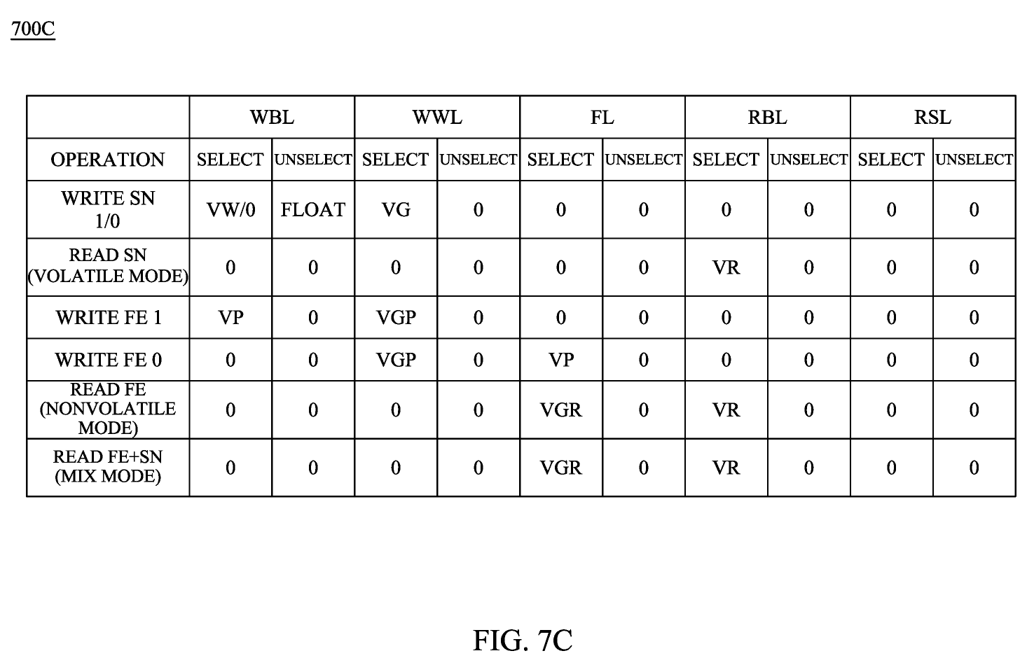

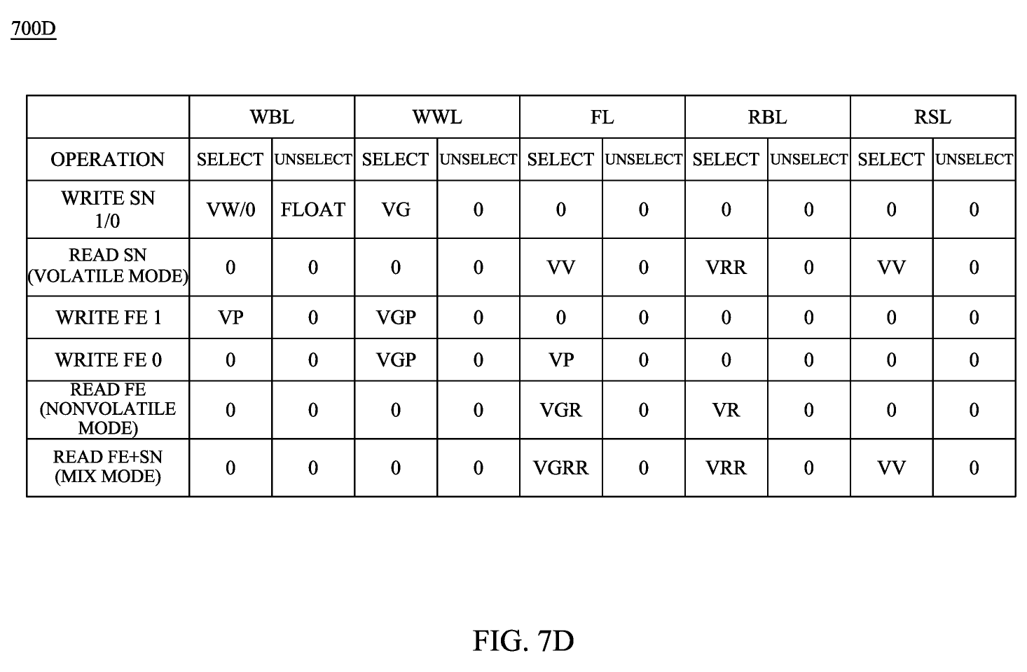

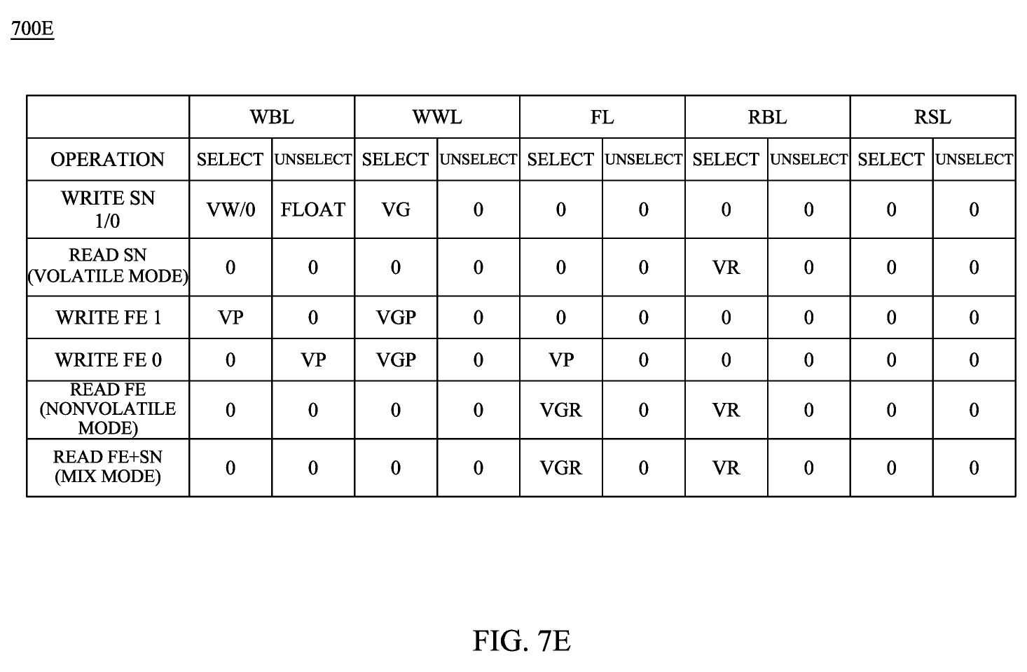

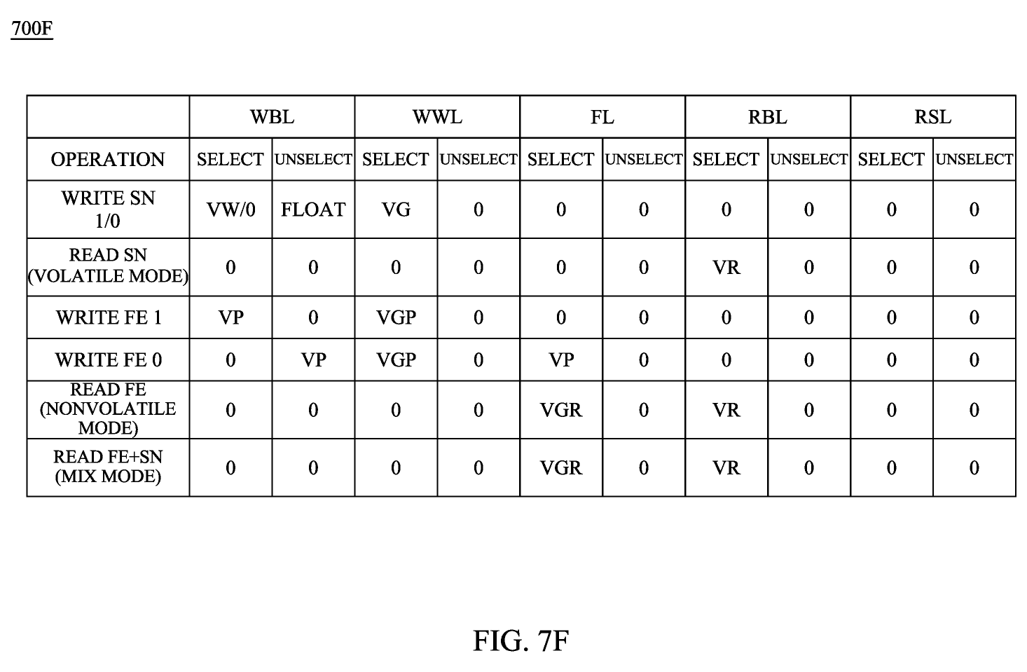

In the embodiment shown in FIG. 5B, during the read operation, the memory device 100A can perform parallel sensing to multiple memory cells in the same row. For example, the memory device 100A can read the memory cells MC1 and MC2 simultaneously, and can also read the memory cells MC3 and MC4 simultaneously. Further details regarding the read operation are described below with the embodiments associated with FIG. 7B.

FIG. 5C is a schematic diagram of a memory array of the memory device 100A during the read operation in the mix mode, illustrated according to some embodiments of present disclosure. In some embodiments, a configuration of the memory array shown in FIG. 5C is referred to as a write AND plus read NOR type. Referring to FIG. 5A and FIG. 5C, the memory array shown in FIG. 5C is an alternative embodiment of the memory array shown in FIG. 5A. Therefore, for brevity, some descriptions are not repeated.

Compared to FIG. 5A, in the embodiment shown in FIG. 5C, two terminals of the switch element RT1 are configured to receive the read signal RSL1 and the read bit line signal RBL1, respectively. Two terminals of the switch element RT2 are configured to receive the read signal RSL1 and the read bit line signal RBL2, respectively. Two terminals of the switch element RT3 are configured to receive the read signal RSL2 and the read bit line signal RBL1, respectively. Two terminals of the switch element RT4 are configured to receive the read signal RSL2 and the read bit line signal RBL2, respectively.

In the embodiment shown in FIG. 5C, during the read operation, the memory device 100A can perform parallel sensing to multiple memory cells in the same row. For example, the memory device 100A can read the memory cells MC1 and MC3 simultaneously, and can also read the memory cells MC2 and MC4 simultaneously. Further details regarding the read operation are described below with the embodiments associated with FIG. 7C.

FIG. 5D is a schematic diagram of a memory array of the memory device 100A during the read operation in the mix mode, illustrated according to some embodiments of present disclosure. In some embodiments, a configuration of the memory array shown in FIG. 5D is referred to as a write NOR plus read AND type. Referring to FIG. 5A and FIG. 5D, the memory array shown in FIG. 5D is an alternative embodiment of the memory array shown in FIG. 5A. Therefore, for brevity, some descriptions are not repeated.

Compared to FIG. 5A, in the embodiment shown in FIG. 5D, two terminals of the switch element WT1 is configured to receive the write bit line signal WBL1 and coupled to the storage node SN1, respectively, and a control terminal of the switch element WT1 is configured to receive the write word line signal WWL1. Two terminals of the switch element WT2 is configured to receive the write bit line signal WBL1 and coupled to the storage node SN2, respectively, and a control terminal of the switch element WT2 is configured to receive the write word line signal WWL2. Two terminals of the switch element WT3 is configured to receive the write bit line signal WBL1 and coupled to the storage node SN3, respectively, and a control terminal of the switch element WT3 is configured to receive the write word line signal WWL1. Two terminals of the switch element WT4 is configured to receive the write bit line signal WBL2 and coupled to the storage node SN4, respectively, and a control terminal of the switch element WT4 is configured to receive the write word line signal WWL2.

FIG. 5E is a schematic diagram of a memory array of the memory device 100A during the read operation in the mix mode, illustrated according to some embodiments of present disclosure. In some embodiments, a configuration of the memory array shown in FIG. 5E is referred to as a write NOR plus read NOR type. Referring to FIG. 5A and FIG. 5E, the memory array shown in FIG. 5E is an alternative embodiment of the memory array shown in FIG. 5A. Therefore, for brevity, some descriptions are not repeated.

Compared to FIG. 5A, in the embodiment shown in FIG. 5E, two terminals of the switch element RT1 are configured to receive the read signal RSL1 and the read bit line signal RBL1, respectively. Two terminals of the switch element RT2 are configured to receive the read signal RSL1 and the read bit line signal RBL2, respectively. Two terminals of the switch element RT3 are configured to receive the read signal RSL2 and the read bit line signal RBL1, respectively. Two terminals of the switch element RT4 are configured to receive the read signal RSL2 and the read bit line signal RBL2, respectively.

Furthermore, two terminals of the storage element FE1 are configured to receive the voltage signal FL1 and coupled to the storage node SN1, respectively. Two terminals of the storage element FE2 are configured to receive the voltage signal FL1 and coupled to the storage node SN2, respectively. Two terminals of the storage element FE3 are configured to receive the voltage signal FL2 and coupled to the storage node SN3, respectively. Two terminals of the storage element FE4 are configured to receive the voltage signal FL2 and coupled to the storage node SN4, respectively.

In the embodiment shown in FIG. 5E, during the read operation, the memory device 100A can perform parallel sensing to multiple memory cells in the same column. For example, the memory device 100A can read the memory cells MC1 and MC3 simultaneously, and can also read the memory cells MC2 and MC4 simultaneously. Further details regarding the read operation are described below with the embodiments associated with FIG. 7E.

FIG. 5F is a schematic diagram of a memory array of the memory device 100A during the read operation in the mix mode, illustrated according to some embodiments of present disclosure. In some embodiments, a configuration of the memory array shown in FIG. 5F is referred to as a write NOR plus read NOR type. Referring to FIG. 5A and FIG. 5F, the memory array shown in FIG. 5F is an alternative embodiment of the memory array shown in FIG. 5A. Therefore, for brevity, some descriptions are not repeated.

Compared to FIG. 5A, in the embodiment shown in FIG. 5F, two terminals of the switch element RT1 are configured to receive the read signal RSL1 and the read bit line signal RBL1, respectively. Two terminals of the switch element RT2 are configured to receive the read signal RSL2 and the read bit line signal RBL1, respectively. Two terminals of the switch element RT3 are configured to receive the read signal RSL1 and the read bit line signal RBL2, respectively. Two terminals of the switch element RT4 are configured to receive the read signal RSL2 and the read bit line signal RBL2, respectively.

Furthermore, two terminals of the storage element FE1 are configured to receive the voltage signal FL1 and coupled to the storage node SN1, respectively. Two terminals of the storage element FE2 are configured to receive the voltage signal FL1 and coupled to the storage node SN2, respectively. Two terminals of the storage element FE3 are configured to receive the voltage signal FL2 and coupled to the storage node SN3, respectively. Two terminals of the storage element FE4 are configured to receive the voltage signal FL2 and coupled to the storage node SN4, respectively.

In the embodiment shown in FIG. 5F, during the read operation, the memory device 100A can perform parallel sensing to multiple memory cells in the same row. For example, the memory device 100A can read the memory cells MC1 and MC2 simultaneously, and can also read the memory cells MC3 and MC4 simultaneously. Further details regarding the read operation are described below with the embodiments associated with FIG. 7F.

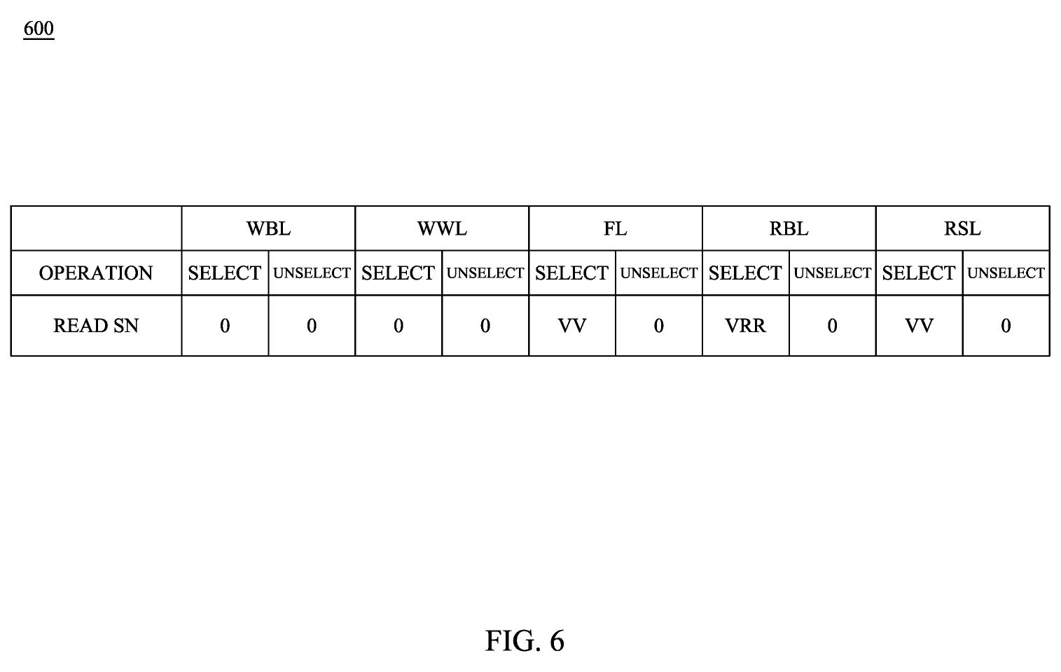

FIG. 6 is a table 600 of the memory device 100A performing the read operation, illustrated according to some embodiments of present disclosure. The storage node SN, the write bit line signal WBL, the write word line signal WWL, the voltage signal FL, the read bit line signal RBL and the read signal RSL can correspond to any memory cell in the memory array.

For example, the storage node SN can correspond to the storage node SN1-SN4. The write bit line signal WBL can correspond to the write bit line signals WBL1 and WBL2. The write word line signal WWL can correspond to the write word line signals WWL1 and WWL2. The voltage signal FL can correspond to the voltage signals FL1 and FL2. The read bit line signal RBL can correspond to the read bit line signals RBL1 and RBL2. The read signal RSL can correspond to the read signals RSL1 and RSL2.

Referring to FIG. 6, FIG. 5A and FIG. 5D, for array configurations of the read AND types, the array bias needs to satisfy the table 600. For illustration purpose, following descriptions are described with the memory cell MC1 being the selected memory cell, and the memory cells MC2-MC4 are unselected memory cells for example. In various embodiments, other memory cells, such as the memory cells MC2-MC4 can also be the selected memory cell.

As shown in the table 600, when reading the storage node SN1, each of the write bit line signals WBL1, WBL2, the write word line signals WWL1, WWL2, the voltage signal FL2, the read bit line signal RBL2 and the read signal RSL2 has the zero-voltage level. Each of the voltage signal FL1 and the read signal RSL1 has a voltage level VV. The read bit line signal RBL1 has a voltage level VRR.

For the selected memory cell MC1, after the logic value 1 is written into the storage node SN1, the storage node SN1 has the voltage level VW. During the read operation, in response to the voltage level VV of the voltage signal FL1, the voltage level of the storage node SN1 is equal to the voltage level VW plus the voltage level VV.

At this moment, for turning on the switch element RT1, a voltage difference between the gate and the source of the switch element RT1 needs to be larger than a threshold voltage level VTH. Alternatively stated, a voltage difference between the storage node SN1 and the read signal RSL1 is larger than the threshold voltage level VTH. Correspondingly, in response to the voltage level VV of the read signal RSL1, the voltage level VW needs to be larger than the voltage level VTH.

On the other hand, for half selected memory cells (for example, the memory cell MC2 shown in FIG. 5A and the memory cell MC3 shown in FIG. 5D), after the logic value 1 is written into the storage node, the storage node has the voltage level VW. During the read operation, in response to the zero-voltage level of the voltage signal FL2, the voltage level of the storage node is equal to the voltage level VW.

At this moment, for maintaining the turning off of the read switch element (for example, the switch element RT2 shown in FIG. 5A and the switch element RT3 shown in FIG. 5D), a voltage difference between the gate and the source of the switch element RT1 needs to be smaller than a threshold voltage level VTH. Alternatively stated, a voltage difference between the storage node SN1 and the read signal RSL1 is smaller than the threshold voltage level VTH. Correspondingly, in response to the voltage level VV of the read signal RSL1, the voltage level VW needs to be smaller than the threshold voltage level VTH plus the voltage level VV. In summary, the voltage level VW is larger than the threshold voltage level VTH and is smaller than the threshold voltage level VTH plus the voltage level VV.

Furthermore, for the selected memory cell MC1, during the read operation, a voltage difference between the drain and the source of the switch element RT1 needs to be larger than zero. Alternatively stated, the voltage level VRR is larger than the voltage level VV, and the voltage level VV is larger than the zero-voltage level.

FIG. 7A is a table 700A of the operations of the memory device 100A shown in FIG. 5A, illustrated according to some embodiments of present disclosure. Referring to FIG. 7A and FIG. 5A, the table 700A corresponds to the write operation and the read operation of the memory array of write AND plus read AND type shown in FIG. 5A. Referring to FIG. 7A and FIG. 6, the table 700A is an alternative embodiment of the table 600. Therefore, for brevity, some descriptions are not repeated.

Compared to the table 600, the table 700A further includes voltage levels associated with the storage element FE. The storage element FE can correspond to the storage elements FE1-FE4. For illustration purpose, the memory cell MC1 is the selected memory cell in following description.

As shown in the table 700A, when performing the write operation to the storage node SN1, each of the write word line signal WWL2, the voltage signals FL1, FL2, the read bit line signals RBL1, RBL2 and the read signals RSL1, RSL2 has the zero-voltage level. In response to writing the logic value 1 into the storage node SN1, the write bit line signal WBL1 has the voltage level VW. In response to writing the logic value 0 into the storage node SN1, the write bit line signal WBL1 has the zero-voltage level. The write bit line signal WBL2 has a floated voltage level. The write word line signal WWL1 has the voltage level VG.

In some embodiments, when performing the write operation to a storage node, memory cells with the same write word line signal can be written at the same time. For example, in response to the write word line signal WWL1 having the voltage level VG, the memory cells MC1 and MC2 are written at the same time.

When performing the read operation to the storage node SN1 in the volatile mode, each of the write bit line signals WBL1, WBL2, the write word line signals WWL1, WWL2, the voltage signal FL2, the read bit line signal RBL2 and the read signal RSL2 has the zero-voltage level. The voltage signal FL1 has the voltage level VV. The read bit line signal RBL1 has the voltage level VRR. The read signal RSL1 has the voltage level VV.

When performing the write operation to the storage element FE1, each of the write bit line signal WBL2, the write word line signal WWL2, the voltage signal FL2, the read bit line signals RBL1, RBL2 and the read signals RSL1, RSL2 has the zero-voltage level. In response to writing the logic value 1 into the storage element FE1, the write bit line signal WBL1 and the voltage signal FL1 have the voltage level VP and the zero-voltage level, respectively. In response to writing the logic value 0 into the storage element FE1, the write bit line signal WBL1 and the voltage signal FL1 have the zero-voltage level and the voltage level VP, respectively.

When performing the read operation to the storage element FE1 in the nonvolatile mode, each of the write bit line signals WBL1, WBL2, the write word line signals WWL1, WWL2, the voltage signal FL2, the read bit line signal RBL2 and the read signals RSL1, RSL2 has the zero-voltage level. The voltage signal FL1 has the voltage level VGR. The read bit line signal RBL1 has the voltage level VR.

When performing the read operation to the storage node SN1 and the storage element FE1 simultaneously in the mix mode, each of the write bit line signals WBL1, WBL2, the write word line signals WWL1, WWL2, the voltage signal FL2, the read bit line signal RBL2 and the read signal RSL2 has the zero-voltage level. The voltage signal FL1 has a voltage level VGRR. The read bit line signal RBL1 has the voltage level VRR. The read signal RSL1 has the voltage level VV.

In some embodiments, the voltage level VW is within a voltage range of 0.8 volt to 2 volt. The voltage level VV is within a voltage range of 0.2 volt to 1.5 volt. The voltage level VRR is within a voltage range of 0.3 volt to 2 volt. The voltage level VGRR is within a voltage range of 0.3 volt to 3.5 volt. The voltage level VR is within a voltage range of 0.1 volt to 0.5 volt.

During the read operation, a voltage difference between a drain and a source of the switch element RT1 needs to be larger than zero, and a voltage difference between a gate and the source of the switch element RT1 also needs to be larger than or equal to zero. Correspondingly, the voltage level VRR is larger than the voltage level VV, and the voltage level VGRR is larger than or equal to the voltage level VV.

FIG. 7B is a table 700B of the operations of the memory device 100A shown in FIG. 5B, illustrated according to some embodiments of present disclosure. Referring to FIG. 7B and FIG. 5B, the table 700B corresponds to the write operation and the read operation of the memory array of write AND plus read NOR type shown in FIG. 5B. Referring to FIG. 7A and FIG. 7B, the table 700B is an alternative embodiment of the table 700A. Therefore, for brevity, some descriptions are not repeated.

As shown in the table 700B, when performing the write operation to the storage node SN1, each of the write word line signal WWL2, the voltage signals FL1, FL2, the read bit line signals RBL1, RBL2 and the read signals RSL1, RSL2 has the zero-voltage level. In response to writing the logic value 1 into the storage node SN1, the write bit line signal WBL1 has the voltage level VW. In response to writing the logic value 0 into the storage node SN1, the write bit line signal WBL1 has the zero-voltage level. The write bit line signal WBL2 has a floated voltage level. The write word line signal WWL1 has the voltage level VG.

In some embodiments, when performing the write operation to a storage node, memory cells with the same write word line signal can be written at the same time. For example, in response to the write word line signal WWL1 having the voltage level VG, the memory cells MC1 and MC2 are written at the same time.

When performing the read operation to the storage node SN1 in the volatile mode, each of the write bit line signals WBL1, WBL2, the write word line signals WWL1, WWL2, the voltage signals FL1, FL2, the read bit line signal RBL2 and the read signal RSL2 has the zero-voltage level. The read bit line signal RBL1 has the voltage level VR. The read signal RSL1 has the zero-voltage level. At this moment, memory cells with the same read bit line signal can be parallel sensed. For example, the memory cells MC1 and MC2 are read at the same time.

When performing the write operation to the storage element FE1, each of the write bit line signal WBL2, the write word line signal WWL2, the voltage signal FL2, the read bit line signals RBL1, RBL2 and the read signals RSL1, RSL2 has the zero-voltage level. In response to writing the logic value 1 into the storage element FE1, the write bit line signal WBL1 and the voltage signal FL1 have the voltage level VP and the zero-voltage level, respectively. In response to writing the logic value 0 into the storage element FE1, the write bit line signal WBL1 and the voltage signal FL1 have the zero-voltage level and the voltage level VP, respectively.

When performing the read operation to the storage element FE1 in the nonvolatile mode, each of the write bit line signals WBL1, WBL2, the write word line signals WWL1, WWL2, the voltage signal FL2, the read bit line signal RBL2 and the read signals RSL1, RSL2 has the zero-voltage level. The voltage signal FL1 has the voltage level VGR. The read bit line signal RBL1 has the voltage level VR. At this moment, by applying the voltage level VGR, multiple memory cells with the same read bit line signal can be parallel sensed. For example, by applying the voltage level VGR to the voltage signals FL1 and FL2, the memory cells MC1 and MC2 are read at the same time.

When performing the read operation to the storage node SN1 and the storage element FE1 simultaneously in the mix mode, each of the write bit line signals WBL1, WBL2, the write word line signals WWL1, WWL2, the voltage signal FL2, the read bit line signal RBL2 and the read signals RSL1, RSL2 has the zero-voltage level. The voltage signal FL1 has a voltage level VGR. The read bit line signal RBL1 has the voltage level VR.

FIG. 7C is a table 700C of the operations of the memory device 100A shown in FIG. 5C, illustrated according to some embodiments of present disclosure. Referring to FIG. 7C and FIG. 5C, the table 700C corresponds to the write operation and the read operation of the memory array of write AND plus read NOR type shown in FIG. 5C. Referring to FIG. 7A and FIG. 7C, the table 700C is an alternative embodiment of the table 700A. Therefore, for brevity, some descriptions are not repeated.

As shown in the table 700C, when performing the write operation to the storage node SN1, each of the write word line signal WWL2, the voltage signals FL1, FL2, the read bit line signals RBL1, RBL2 and the read signals RSL1, RSL2 has the zero-voltage level. In response to writing the logic value 1 into the storage node SN1, the write bit line signal WBL1 has the voltage level VW. In response to writing the logic value 0 into the storage node SN1, the write bit line signal WBL1 has the zero-voltage level. The write bit line signal WBL2 has a floated voltage level. The write word line signal WWL1 has the voltage level VG.

In some embodiments, when performing the write operation to a storage node, memory cells with the same write word line signal can be written at the same time. For example, in response to the write word line signal WWL1 having the voltage level VG, the memory cells MC1 and MC2 are written at the same time.

When performing the read operation to the storage node SN1 in the volatile mode, each of the write bit line signals WBL1, WBL2, the write word line signals WWL1, WWL2, the voltage signals FL1, FL2, the read bit line signal RBL2 and the read signal RSL2 has the zero-voltage level. The read bit line signal RBL1 has the voltage level VR. The read signal RSL1 has the zero-voltage level. At this moment, memory cells with the same read bit line signal can be parallel sensed. For example, the memory cells MC1 and MC2 are read at the same time.

When performing the write operation to the storage element FE1, each of the write bit line signal WBL2, the write word line signal WWL2, the voltage signal FL2, the read bit line signals RBL1, RBL2 and the read signals RSL1, RSL2 has the zero-voltage level. In response to writing the logic value 1 into the storage element FE1, the write bit line signal WBL1 and the voltage signal FL1 have the voltage level VP and the zero-voltage level, respectively. In response to writing the logic value 0 into the storage element FE1, the write bit line signal WBL1 and the voltage signal FL1 have the zero-voltage level and the voltage level VP, respectively.

When performing the read operation to the storage element FE1 in the nonvolatile mode, each of the write bit line signals WBL1, WBL2, the write word line signals WWL1, WWL2, the voltage signal FL2, the read bit line signal RBL2 and the read signals RSL1, RSL2 has the zero-voltage level. The voltage signal FL1 has the voltage level VGR. The read bit line signal RBL1 has the voltage level VR. At this moment, by applying the voltage level VR, multiple memory cells with the same read bit line signal can be parallel sensed. For example, by applying the voltage level VR to the read bit line signal RBL1, the memory cells MC1 and MC3 are read at the same time.

When performing the read operation to the storage node SN1 and the storage element FE1 simultaneously in the mix mode, each of the write bit line signals WBL1, WBL2, the write word line signals WWL1, WWL2, the voltage signal FL2, the read bit line signal RBL2 and the read signals RSL1, RSL2 has the zero-voltage level. The voltage signal FL1 has a voltage level VGR. The read bit line signal RBL1 has the voltage level VR.

FIG. 7D is a table 700D of the operations of the memory device 100A shown in FIG. 5D, illustrated according to some embodiments of present disclosure. Referring to FIG. 7D and FIG. 5D, the table 700D corresponds to the write operation and the read operation of the memory array of write NOR plus read AND type shown in FIG. 5D. Referring to FIG. 7A and FIG. 7D, the table 700D is an alternative embodiment of the table 700A. Therefore, for brevity, some descriptions are not repeated.

As shown in the table 700D, when performing the write operation to the storage node SN1, each of the write word line signal WWL2, the voltage signals FL1, FL2, the read bit line signals RBL1, RBL2 and the read signals RSL1, RSL2 has the zero-voltage level. In response to writing the logic value 1 into the storage node SN1, the write bit line signal WBL1 has the voltage level VW. In response to writing the logic value 0 into the storage node SN1, the write bit line signal WBL1 has the zero-voltage level. The write bit line signal WBL2 has a floated voltage level. The write word line signal WWL1 has the voltage level VG.

In some embodiments, when performing the write operation to a storage node, memory cells with the same write word line signal can be written at the same time. For example, in response to the write word line signal WWL1 having the voltage level VG, the memory cells MC1 and MC3 are written at the same time.

When performing the read operation to the storage node SN1 in the volatile mode, each of the write bit line signals WBL1, WBL2, the write word line signals WWL1, WWL2, the voltage signal FL2, the read bit line signal RBL2 and the read signal RSL2 has the zero-voltage level. The voltage signal FL1 has the voltage level VV. The read bit line signal RBL1 has the voltage level VRR. The read signal RSL1 has the voltage level VV.

When performing the write operation to the storage element FE1, each of the write bit line signal WBL2, the write word line signal WWL2, the voltage signal FL2, the read bit line signals RBL1, RBL2 and the read signals RSL1, RSL2 has the zero-voltage level. In response to writing the logic value 1 into the storage element FE1, the write bit line signal WBL1 and the voltage signal FL1 have the voltage level VP and the zero-voltage level, respectively. In response to writing the logic value 0 into the storage element FE1, the write bit line signal WBL1 and the voltage signal FL1 have the zero-voltage level and the voltage level VP, respectively.

When performing the read operation to the storage element FE1 in the nonvolatile mode, each of the write bit line signals WBL1, WBL2, the write word line signals WWL1, WWL2, the voltage signal FL2, the read bit line signal RBL2 and the read signals RSL1, RSL2 has the zero-voltage level. The voltage signal FL1 has the voltage level VGR. The read bit line signal RBL1 has the voltage level VR.

When performing the read operation to the storage node SN1 and the storage element FE1 simultaneously in the mix mode, each of the write bit line signals WBL1, WBL2, the write word line signals WWL1, WWL2, the voltage signal FL2, the read bit line signal RBL2 and the read signal RSL2 has the zero-voltage level. The voltage signal FL1 has a voltage level VGRR. The read bit line signal RBL1 has the voltage level VRR. The read signal RSL1 has the voltage level VV.

FIG. 7E is a table 700E of the operations of the memory device 100A shown in FIG. 5E, illustrated according to some embodiments of present disclosure. Referring to FIG. 7E and FIG. 5E, the table 700E corresponds to the write operation and the read operation of the memory array of write NOR plus read NOR type shown in FIG. 5E. Referring to FIG. 7A and FIG. 7E, the table 700E is an alternative embodiment of the table 700A. Therefore, for brevity, some descriptions are not repeated.

As shown in the table 700E, when performing the write operation to the storage node SN1, each of the write word line signal WWL2, the voltage signals FL1, FL2, the read bit line signals RBL1, RBL2 and the read signals RSL1, RSL2 has the zero-voltage level. In response to writing the logic value 1 into the storage node SN1, the write bit line signal WBL1 has the voltage level VW. In response to writing the logic value 0 into the storage node SN1, the write bit line signal WBL1 has the zero-voltage level. The write bit line signal WBL2 has a floated voltage level. The write word line signal WWL1 has the voltage level VG.

In some embodiments, when performing the write operation to a storage node, memory cells with the same write word line signal can be written at the same time. For example, in response to the write word line signal WWL1 having the voltage level VG, the memory cells MC1 and MC2 are written at the same time.

When performing the read operation to the storage node SN1 in the volatile mode, each of the write bit line signals WBL1, WBL2, the write word line signals WWL1, WWL2, the voltage signals FL1, FL2, the read bit line signal RBL2 and the read signal RSL2 has the zero-voltage level. The read bit line signal RBL1 has the voltage level VR. The read signal RSL1 has the zero-voltage level. At this moment, memory cells with the same read bit line signal can be parallel sensed. For example, the memory cells MC1 and MC3 are read at the same time.

When performing the write operation to the storage element FE1, each of the write bit line signal WBL2, the write word line signal WWL2, the voltage signal FL2, the read bit line signals RBL1, RBL2 and the read signals RSL1, RSL2 has the zero-voltage level. In response to writing the logic value 1 into the storage element FE1, the write bit line signals WBL1, WBL2 and the voltage signal FL1 have the voltage level VP, the zero-voltage level and the zero-voltage level, respectively. In response to writing the logic value 0 into the storage element FE1, the write bit line signals WBL1, WBL2 and the voltage signal FL1 have the zero-voltage level, the voltage level VP and the voltage level VP, respectively.

When performing the read operation to the storage element FE1 in the nonvolatile mode, each of the write bit line signals WBL1, WBL2, the write word line signals WWL1, WWL2, the voltage signal FL2, the read bit line signal RBL2 and the read signals RSL1, RSL2 has the zero-voltage level. The voltage signal FL1 has the voltage level VGR. The read bit line signal RBL1 has the voltage level VR. At this moment, by applying the voltage level VR, multiple memory cells with the same read bit line signal can be parallel sensed. For example, by applying the voltage level VR to the read bit line signal RBL1, the memory cells MC1 and MC3 are read at the same time.

When performing the read operation to the storage node SN1 and the storage element FE1 simultaneously in the mix mode, each of the write bit line signals WBL1, WBL2, the write word line signals WWL1, WWL2, the voltage signal FL2, the read bit line signal RBL2 and the read signals RSL1, RSL2 has the zero-voltage level. The voltage signal FL1 has a voltage level VGR. The read bit line signal RBL1 has the voltage level VR.

FIG. 7F is a table 700F of the operations of the memory device 100A shown in FIG. 5F, illustrated according to some embodiments of present disclosure. Referring to FIG. 7F and FIG. 5F, the table 700F corresponds to the write operation and the read operation of the memory array of write NOR plus read NOR type shown in FIG. 5F. Referring to FIG. 7A and FIG. 7F, the table 700F is an alternative embodiment of the table 700A. Therefore, for brevity, some descriptions are not repeated.

As shown in the table 700F, when performing the write operation to the storage node SN1, each of the write word line signal WWL2, the voltage signals FL1, FL2, the read bit line signals RBL1, RBL2 and the read signals RSL1, RSL2 has the zero-voltage level. In response to writing the logic value 1 into the storage node SN1, the write bit line signal WBL1 has the voltage level VW. In response to writing the logic value 0 into the storage node SN1, the write bit line signal WBL1 has the zero-voltage level. The write bit line signal WBL2 has a floated voltage level. The write word line signal WWL1 has the voltage level VG.

In some embodiments, when performing the write operation to a storage node, memory cells with the same write word line signal can be written at the same time. For example, in response to the write word line signal WWL1 having the voltage level VG, the memory cells MC1 and MC2 are written at the same time.

When performing the read operation to the storage node SN1 in the volatile mode, each of the write bit line signals WBL1, WBL2, the write word line signals WWL1, WWL2, the voltage signals FL1, FL2, the read bit line signal RBL2 and the read signal RSL2 has the zero-voltage level. The read bit line signal RBL1 has the voltage level VR. The read signal RSL1 has the zero-voltage level. At this moment, memory cells with the same read bit line signal can be parallel sensed. For example, the memory cells MC1 and MC2 are read at the same time.

When performing the write operation to the storage element FE1, each of the write bit line signal WBL2, the write word line signal WWL2, the voltage signal FL2, the read bit line signals RBL1, RBL2 and the read signals RSL1, RSL2 has the zero-voltage level. In response to writing the logic value 1 into the storage element FE1, the write bit line signals WBL1, WBL2 and the voltage signal FL1 have the voltage level VP, the zero-voltage level and the zero-voltage level, respectively. In response to writing the logic value 0 into the storage element FE1, the write bit line signals WBL1, WBL2 and the voltage signal FL1 have the zero-voltage level, the voltage level VP and the voltage level VP, respectively.

When performing the read operation to the storage element FE1 in the nonvolatile mode, each of the write bit line signals WBL1, WBL2, the write word line signals WWL1, WWL2, the voltage signal FL2, the read bit line signal RBL2 and the read signals RSL1, RSL2 has the zero-voltage level. The voltage signal FL1 has the voltage level VGR. The read bit line signal RBL1 has the voltage level VR. At this moment, by applying the voltage level VR, multiple memory cells with the same read bit line signal can be parallel sensed. For example, by applying the voltage level VR to the read bit line signal RBL1, the memory cells MC1 and MC2 are read at the same time.

When performing the read operation to the storage node SN1 and the storage element FE1 simultaneously in the mix mode, each of the write bit line signals WBL1, WBL2, the write word line signals WWL1, WWL2, the voltage signal FL2, the read bit line signal RBL2 and the read signals RSL1, RSL2 has the zero-voltage level. The voltage signal FL1 has a voltage level VGR. The read bit line signal RBL1 has the voltage level VR.

In summary, the memory device 100A can perform the write operation and the read operation by various configurations of the memory array in the volatile mode, the nonvolatile mode and the mix mode. Furthermore, compared to other approaches, the embodiments of present disclosure has a lower write voltage and a better endurance, such that a performance of the memory device 100A is better.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory device, comprising a memory cell, the memory cell comprising:
a first switch element configured to receive a write bit line signal, and coupled to a storage node;
a second switch element configured to receive a read bit line signal, and coupled to the storage node; and
a storage element coupled to the storage node, and configured to receive a voltage signal and store a first data bit,
wherein the memory cell is configured to store a second data bit different from the first data bit at the storage node.

2. The memory device of claim 1, wherein when the first data bit is written into the memory cell, one of the write bit line signal and the voltage signal has a first voltage level, and the other one of the write bit line signal and the voltage signal has a second voltage level,
when reading the first data bit, the voltage signal has a third voltage level, and
the third voltage level is larger than the first voltage level and is smaller than the second voltage level.

3. The memory device of claim 2, wherein when the second data bit is written into the memory cell, in response to the second data bit having a first logic value, the write bit line signal has the first voltage level,
when the second data bit is written into the memory cell, in response to the second data bit having a second logic value, the write bit line signal has a fourth voltage level,
the fourth voltage level is larger than the first voltage level and is smaller than the second voltage level.

4. The memory device of claim 1, wherein when the first data bit and the second data bit are read at the same time, the memory cell generates a read current signal passing through the second switch element,
when the first data bit has a first logic value, a current level of the read current signal is larger than a first preset current level, and
when the first data bit has a second logic value, the current level of the read current signal is smaller than the first preset current level.

5. The memory device of claim 4, wherein when each of the first data bit and the second data bit has the first logic value, the current level of the read current signal is between the first preset current level and a second preset current level, and
when the first data bit and the second data bit respectively have the first logic value and the second logic value, the current level of the read current signal is larger than the second preset current level.

6. The memory device of claim 5, wherein when each of the first data bit and the second data bit has the second logic value, the current level of the read current signal is between the first preset current level and a third preset current level, and
when the first data bit and the second data bit respectively have the second logic value and the first logic value, the current level of the read current signal is smaller than the third preset current level.

7. A memory array, comprising a plurality of memory cells, the plurality of memory cells comprising:
a first memory cell configured to receive a first read bit line signal, a first read signal and a first voltage signal;
a second memory cell configured to receive at least one of the first read bit line signal and the first read signal; and
a third memory cell configured to receive at least one of the first read bit line signal, the first read signal and the first voltage signal,
wherein when a first data bit is written into the first memory cell, the first voltage signal has a first voltage level,
when a second data bit is written into the first memory cell, in response to the second data bit having a first logic value, the first voltage signal has a second voltage level larger than the first voltage level, and
when the second data bit is written into the first memory cell, in response to the second data bit having a second logic value, the first voltage signal has the first voltage level.

8. The memory array of claim 7, wherein the second memory cell is configured to receive each of the first read bit line signal and the first read signal,
the third memory cell is configured to receive the first voltage signal,
when the first data bit is read, each of the first voltage signal and the first read signal has a third voltage level larger than the first voltage level, and the first read bit line signal has a fourth voltage level larger than the first voltage level.

9. The memory array of claim 8, wherein a switch element in the first memory cell is configured to receive each of the first read bit line signal and the first read signal, and has a threshold voltage level,
when the first data bit is written into the first memory cell, in response to the first data bit having the second logic value, a control terminal of the switch element has a fifth voltage level larger than the threshold voltage level, and
the fifth voltage level is smaller than the third voltage level plus the threshold voltage level.

10. The memory array of claim 9, wherein each of the first memory cell and the third memory cell is configured to receive a first write bit line signal,
when the second data bit is written into the first memory cell, in response to the second data bit having the first logic value, the first write bit line signal has the first voltage level, and
when the second data bit is written into the first memory cell, in response to the second data bit having the second logic value, the first write bit line signal has the second voltage level.

11. The memory array of claim 9, wherein each of the first memory cell and the second memory cell is configured to receive a first write bit line signal,
the third memory cell is configured to receive a second write bit line signal,
when the second data bit is written into the first memory cell, in response to the second data bit having the first logic value, the first write bit line signal and the second write bit line signal have the first voltage level and the second voltage level, respectively, and
when the second data bit is written into the first memory cell, in response to the second data bit having the second logic value, the first write bit line signal and the second write bit line signal have the second voltage level and the first voltage level, respectively.

12. The memory array of claim 7, wherein the second memory cell is configured to receive the first read signal,
the third memory cell is configured to receive the first read bit line signal,
when at least one of the first data bit and the second data bit is read, the first read signal and the first read bit line signal have the first voltage level and a third voltage level, respectively, to read the first memory cell and the third memory cell at the same time, and
the third voltage level is larger than the first voltage level and is smaller than the second voltage level.

13. The memory array of claim 12, wherein each of the first memory cell and the third memory cell is configured to receive a first write bit line signal and the first voltage signal,
when the second data bit is written into the first memory cell, in response to the second data bit having the first logic value, the first write bit line signal has the first voltage level, and
when the second data bit is written into the first memory cell, in response to the second data bit having the second logic value, the first write bit line signal has the second voltage level.

14. The memory array of claim 12, wherein each of the first memory cell and the third memory cell is configured to receive a first write bit line signal and ,
the second memory cell is configured to receive a second write bit line signal and the first voltage signal,
when the second data bit is written into the first memory cell, in response to the second data bit having the first logic value, the first write bit line signal and the second write bit line signal have the first voltage level and the second voltage level, respectively, and
when the second data bit is written into the first memory cell, in response to the second data bit having the second logic value, the first write bit line signal and the second write bit line signal have the second voltage level and the first voltage level, respectively.

15. The memory array of claim 7, wherein the second memory cell is configured to receive the first read bit line signal,
the third memory cell is configured to receive the first read signal,
when at least one of the first data bit and the second data bit is read, the first read signal and the first read bit line signal have the first voltage level and a third voltage level, respectively, to read the first memory cell and the second memory cell at the same time, and
the third voltage level is larger than the first voltage level and is smaller than the second voltage level.

16. The memory array of claim 15, wherein each of the first memory cell and the third memory cell is configured to receive a first write bit line signal and the first voltage signal,
when the second data bit is written into the first memory cell, in response to the second data bit having the first logic value, the first write bit line signal has the first voltage level, and
when the second data bit is written into the first memory cell, in response to the second data bit having the second logic value, the first write bit line signal has the second voltage level.

17. The memory array of claim 15, wherein each of the first memory cell and the third memory cell is configured to receive a first write bit line signal and ,
the second memory cell is configured to receive a second write bit line signal and the first voltage signal,
when the second data bit is written into the first memory cell, in response to the second data bit having the first logic value, the first write bit line signal and the second write bit line signal have the first voltage level and the second voltage level, respectively, and
when the second data bit is written into the first memory cell, in response to the second data bit having the second logic value, the first write bit line signal and the second write bit line signal have the second voltage level and the first voltage level, respectively.

18. An operation method of a memory device, comprising:
receiving a write bit line signal by a first switch element coupled to a storage node;
receiving a read bit line signal by a second switch element coupled to the storage node;
receiving a voltage signal by a storage element coupled to the storage node;
storing a first data bit by the storage element; and
storing a second data bit different from the first data bit at the storage node.

19. The operation method of claim 18, further comprising:
when the first data bit and the second data bit are read at the same time, generating a read current signal passing through the second switch element,
wherein when the first data bit has a first logic value, a current level of the read current signal is larger than a first preset current level, and
when the first data bit has a second logic value, the current level of the read current signal is smaller than the first preset current level.

20. The operation method of claim 19, wherein when each of the first data bit and the second data bit has the first logic value, the current level of the read current signal is between the first preset current level and a second preset current level,
when the first data bit and the second data bit respectively have the first logic value and the second logic value, the current level of the read current signal is larger than the second preset current level,
when each of the first data bit and the second data bit has the second logic value, the current level of the read current signal is between the first preset current level and a third preset current level, and
when the first data bit and the second data bit respectively have the second logic value and the first logic value, the current level of the read current signal is smaller than the third preset current level.
